(19) United States
(12) Patent Application Publication
(10) Pub. No.: US 2013/0000547 A1
(43) Pub. Date: Jan. 3, 2013

(54) METHOD FOR FIXING SILICON CARBIDE SEED CRYSTAL AND METHOD FOR PRODUCING SINGLE CRYSTAL SILICON CARBIDE

(75) Inventor: Hisao Kogoi, Hikone-shi (JP)

(73) Assignee: SHOWA DENKO K.K., Minato-ku, Tokyo (JP)

(21) Appl. No.: 13/582,592

(22) PCT Filed: Mar. 2, 2011
(86) PCT No.: PCT/JP2011/054766

§ 371 Date: Sep. 4, 2012

(30) Foreign Application Priority Data
Mar. 5, 2010 (JP) 2010-049627

(51) Int. Cl. C30B 23/02

(52) U.S. Cl. 117/106

(57) ABSTRACT

The object of the present invention is to provide a method for fixing a silicon carbide seed crystal and a method for producing a silicon carbide single crystal which can produce a silicon carbide single crystal having high quality and no penetration defects, and the present invention provides a method for fixing a silicon carbide seed crystal on a pedestal including: a step of mirror polishing a surface of a pedestal on which a silicon carbide seed crystal is to be fixed; a step of irradiating atoms or ions to at least one of a seed crystal-side surface of the pedestal on which the silicon carbide seed crystal is to be fixed and a pedestal side-surface of the silicon carbide seed crystal which is to be fixed on the pedestal, in a vacuum; and a step of directly connecting the seed crystal side-surface of the pedestal and the pedestal side-surface of the silicon carbide seed crystal by bringing them into close contact and applying pressure to them in a vacuum.

### TECHNICAL FIELD

The present invention relates to a method for fixing a silicon carbide seed crystal and a method for producing a silicon carbide single crystal.

### BACKGROUND ART

Silicon carbides are physically and chemically stable, for example, silicon carbides have high thermal conductivity, excellent thermal resistance, methanical strength, and resistance to radial rays. In addition, silicon carbides have a feature of having a large energy band-gap. Therefore, silicon carbides are expected to be used in light emitting devices, high-electrical power devices, high-temperature resistant elements, radical ray resistant elements, high-frequency elements, and the like.

As a method for producing a silicon carbide single crystal, a method, in which a silicon carbide seed crystal is fixed on a pedestal made of graphite, for example, and a silicon carbide single crystal is grown on the silicon carbide seed crystal by supplying a sublimation gas containing a silicon carbide raw material, has been known.

As a method for fixing a silicon carbide seed crystal on a pedestal, Patent Document No. 1 discloses a method in which an underside of the seed crystal is covered with an organic thin film having a thickness of 0.5 to 5 μm, and then the seed crystal is fixed on the pedestal.

In addition, Patent Document No. 2 discloses a method in which a surface to be adhered of the seed crystal is polished, RIE, or the like, and then the treated surface is adhered on the pedestal.

Patent Document No. 3 discloses a method in which an underside of the seed crystal is covered with a material, which is stable at high temperatures, and then the seed crystal is attached to the pedestal.

Patent Document No. 4 discloses a method for attaching the seed crystal to the pedestal by inserting a stress buffer layer between the surface of the pedestal and the surface of the seed crystal which is adhered to the pedestal.

Furthermore, Patent Document No. 5 discloses an adhesive for adhering the seed crystal on the pedestal.

### PRIOR DOCUMENTS

### Patent Document

[Patent Document 1] Japanese Patent No. 4054197

[Patent Document 2] Japanese Unexamined Patent Application, First Publication No. 2003-119098

[Patent Document 3] Japanese Unexamined Patent Application, First Publication No. H 09-268096

[Patent Document 4] Japanese Unexamined Patent Application, First Publication No. 2004-269297

[Patent Document 5] Japanese Patent No. 4258921

### SUMMARY OF INVENTION

### Technical Problem

However, the method disclosed in Patent Document 1 has problems that when a protective film is obtained by carbonizing the organic thin film, the organic thin film itself is thermally decomposed, generates decomposition gases, such as methane, and ethylene, the generated decomposition gasses make the protective film porous, thereby decreasing the gas barrier properties of the protective film, and due to this, effects of the protective film for preventing the sublimation from the underside of the seed crystal are decreased.

In addition, in a method for fixing the seed crystal on the pedestal using an adhesive, bubbles are generated in an adhesive layer in a thermal-treatment step for drying and solidifying the adhesive, and the bubbles are sometimes remained in the adhesive layer as voids. The seed crystal cannot release heat to the pedestal at the place having voids. As a result, the temperature gradient is locally generated between the seed crystal and the pedestal. Then, the sublimation of the seed crystal generates from the underside of the seed crystal to the low-temperature pedestal. This causes a problem of generating a penetration defect called micro-pipe.

Furthermore, in the method for fixing the seed crystal on the pedestal by inserting the stress buffer layer between the surface of the pedestal and the surface of the seed crystal which is adhered to the pedestal, when the stress buffer layer does not have sufficient high thermal conductivity, heat radiation of the grown silicon carbide single crystal to the pedestal is prevented. Then, the growth rate of the single crystal is lowered, and in-plane temperature distribution of the grown crystal is ununiform and this causes crystal defects in the single crystal.

In consideration of the above-described problems, it is an object of the present invention to provide a method for fixing a silicon carbide seed crystal which can produce a silicon carbide single crystal having no penetration defects by directly fixing the silicon carbide seed crystal on the pedestal without a film, adhesive, or the like between the silicon carbide seed crystal and the pedestal, uniforming the temperature at the underside (a surface to be fixed) of the silicon carbide seed crystal, preventing partial sublimation of the silicon carbide seed crystal from the underside thereof, and thereby inhibiting the generation of the penetration defects in the silicon carbide single crystal. In addition, it is also an object of the present invention to provide a method for producing a silicon carbide single crystal using the method for fixing a silicon carbide seed crystal.

### Solution to Problem

In order to attain the foregoing objects, the present provides the following inventions.
(1) A method for fixing a silicon carbide seed crystal on a pedestal including:
   a step of mirror polishing a surface of a pedestal on which a silicon carbide seed crystal is to be fixed;
   a step of irradiating atoms or ions to at least one of a seed crystal-side surface of the pedestal on which the silicon carbide seed crystal is to be fixed and a pedestal side-surface of the silicon carbide seed crystal which is to be fixed on the pedestal, in a vacuum; and
   a step of directly connecting the seed crystal side-surface of the pedestal and the pedestal side-surface of the silicon carbide seed crystal by bringing them into close contact and applying pressure to them in a vacuum.
(2) The method for fixing a silicon carbide seed crystal according to (1), wherein the method further includes a step of polishing the pedestal side-surface of the silicon carbide seed crystal before the step of irradiating.
(3) The method for fixing a silicon carbide seed crystal according to (1) or (2), wherein the seed crystal side-surface of the pedestal and/or the pedestal side-surface of the silicon carbide seed crystal is mirror polished such that a root-mean-square of a roughness at the surface is 0.3 nm or less in the step of mirror polishing.
(4) The method for fixing a silicon carbide seed crystal according to any one of (1) to (3), wherein the atoms and ions irradiated in the step of irradiating is one selected from the group consisting of hydrogen atoms (H), hydrogen molecules (H₂), and hydrogen ions (H⁺).
(5) The method for fixing a silicon carbide seed crystal according to any one of (1) to (3), wherein the atoms and ions irradiated in the step of irradiating is at least one selected from the group consisting of helium (He), neon (Ne), argon (Ar), and krypton (Kr).
(6) The method for fixing a silicon carbide seed crystal according to any one of (1) to (5), wherein the method further includes a step of wet-etching or dry-etching at least one of the seed crystal side-surface of the pedestal and the pedestal side-surface of the silicon carbide seed crystal before the step of irradiating.
(7) The method for fixing a silicon carbide seed crystal according to any one of (1) to (6), wherein the temperature for directly connecting the seed crystal side-surface of the pedestal and the pedestal side-surface of the silicon carbide seed crystal is room temperature or higher and 200° C. or lower.
(8) A method for producing a silicon carbide single crystal wherein using the method according to any one of (1) to (7), a silicon carbide single crystal is grown on the silicon carbide seed crystal by supplying a sublimation gas containing a silicon carbide raw material to the silicon carbide seed crystal which is fixed on the pedestal made of a carbon material.

### Advantageous Effects of Invention

According to the method for fixing a silicon carbide seed crystal of present invention, it is possible to uniform the temperature at the underside (to be fixed to the pedestal) of the silicon carbide seed crystal, and prevent the partial sublimation from the underside of the silicon carbide seed crystal.

In addition, according to the method for producing a silicon carbide single crystal, it is possible to product a silicon carbide single crystal having high quality and no penetration defects.

### BRIEF DESCRIPTION OF DRAWINGS

FIG. 1 is a sectional schematic view showing a device for silicon carbide single crystal growth.

FIG. 2 is a sectional schematic view showing the circumference of the device for silicon carbide single crystal growth shown in FIG. 1.

### DESCRIPTION OF EMBODIMENTS

Below, the embodiments of the method for fixing a silicon carbide seed crystal and the method for producing a silicon carbide single crystal according to the present invention are explained in detail with reference to the attached figures.

Moreover, in the figures used in the following embodiments, for convenience, the characteristic part may be enlarged, and the proportion of each element shown in the figures may be different from the actual proportion in order to show clearly the characteristic part.

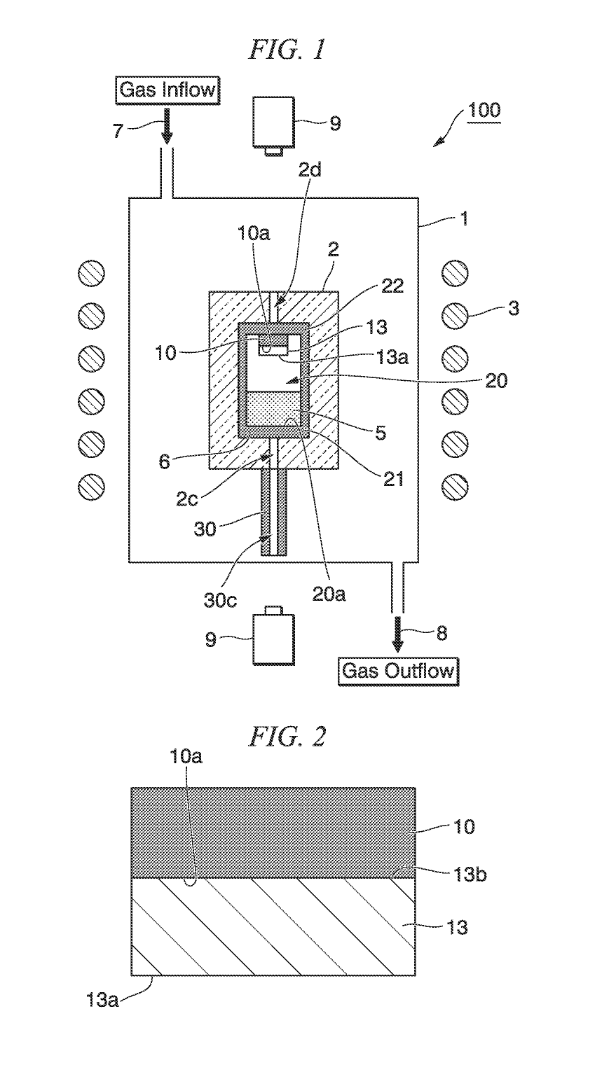

FIG. 1 shows a device for single crystal growth used in the method for fixing a silicon carbide seed crystal and the method for producing a silicon carbide single crystal according to the present invention.

A single crystal growth device 100 includes a vacuum chamber 1. In the vacuum chamber 1, there is a crucible 6 which is made of graphite and covered with a heat insulating material 2. The crucible 6 includes a lid 22 and a body part 21.

As shown in FIG. 1, a cylindrical pedestal 10 is provided on one surface of the lid 22 so as to protrude. When the lid 22 is put on the body part 21, the pedestal 10 protrudes from the lid 22 toward the inner bottom 20a. In addition, the pedestal 10 has a seed crystal side-surface 10a (surface toward a seed crystal) for arranging the silicon carbide seed crystal 13 which faces toward the inner bottom 20a. A silicon carbide seed crystal is fixed to the seed crystal side-surface 10a of the pedestal 10.

The body part 21 of the crucible 6 made of graphite has a hollow portion 20 inside thereof. To the upper portion of the hollow portion 20, the silicon carbide seed crystal 13 is fixed. On the other hand, an amount of silicon carbide raw material powders 5, which is sufficient for the crystal growth of the silicon carbide single crystal on the silicon carbide seed crystal 13, are filled in the lower portion of the hollow portion 20.

In other words, the hollow portion 20 stores a sufficient amount of the silicon carbide raw material 5, while maintaining a space in upper portion which is sufficient for the crystal growth of the silicon carbide single crystal. Therefore, it is possible to grow the silicon carbide single crystal on a growth surface 13a of the silicon carbide seed crystal toward the inner bottom 20a by the sublimation recrystallization.

As explained above, the heat insulating material 2 is arranged so as to cover the entire of the crucible 6 including the lid 22 and the body part 21. In the heat insulating material 2, holes 2c and 2d are formed such that a part of the bottom surface and upper surface of the crucible 6 is exposed. The heat insulating material 2 is for stably maintaining the temperature of the crucible 6 high. For example, the heat insulating material 2 may contain carbon fibers. In a case that the temperature of the crucible 6 can be stably maintained high as desired, the heat insulating material 2 may be omitted.

The crucible 6 covered with the heat insulating material 2 is arranged on a support bar 20 so as to be positioned at the inner center of the vacuum chamber 1. The support bar 20 is cylindrical, and has a hole 30c inside thereof. The crucible 6 and the support bar 20 are positioned such that the hole 30c of the support bar 20 corresponds to a hole 2c formed in the heat insulating material 2. Due to this, it is possible to measure the temperature at the bottom surface of the crucible 6 using a radiation thermometer 9 arranged under the vacuum chamber 1 through the hole 30c of the support bar 30 and the hole 2c formed at the lower side of the heat insulating material 2. Similar to this, it is also possible to examine the temperature at the upper surface of the crucible 6 using another radiation thermometer 9 arranged above the vacuum chamber 1 through the hole 2d formed at the upper side of the heat insulating material 2.

A gas inflow pipe 7 is provided in the upper portion of the vacuum chamber I. A gas outflow pipe 8 is provided in the lower portion of the vacuum chamber 1. The inside of the vacuum chamber 1 is filled with Ar, for example, and the pressure is adjusted to about 9.3×10⁴ Pa. First, using a vacuum pump (not shown in figures) fixed with the gas outflow pipe 8, the air inside the vacuum chamber 1 is discharged, and reduces the pressure to 4×10⁻³ Pa or less, for example. As the vacuum pump, for example a turbo-molecular pump can be used. After that, high-purity Ar gas is introduced into the inside of the vacuum chamber 1 from the gas inflow pipe 7, and thereby makes the inside of the vacuum chamber 1 be an Ar gas atmosphere at 9.3×10⁴ Pa.

A heating device 3 is provided outside the vacuum chamber 1. The heating device 3 may be a high-frequency heating coil, for example. It is possible to heat the crucible 6 made of graphite which is positioned at the center inside the vacuum chamber 1 to 1,900° C. or more by flowing current to the high-frequency heating coil to generate high frequency. Thereby, the silicon carbide raw material powder 5 in the crucible 6 made of graphite is heated to generate the sublimation gas from the silicon carbide raw material powder 5.

FIG. 2 is a sectional schematic view showing the circumference of the pedestal 10.

As the material for the pedestal 10, carbon material such as graphite, dense graphite, glassy carbon, and pyrolytic graphite can be used. In addition, the carbon material covered with tantalum carbide may also be used. Furthermore, silicon carbide is also used as the material for the pedestal 10. Polycrystal, monocrystal, or sintered silicon carbide can be used.

In addition, as the material for the pedestal 10, metal carbides having a high melting point, such as WC, ZrC, NbC, TiC, and MoC can also be used. The metals of which the surface is carbonized can also be used.

Among these, the material for the pedestal 10 is preferably a material which is easily processed. Therefore, the material for the pedestal 10 is preferably dense graphite, glassy carbon, pyrolytic graphite or silicon carbide.

The pedestal 10 has a function for directly connecting to a seed crystal. The lid 22 having the pedestal 10 works as a lid of the crucible 6.

The pedestal 10 and the lid 22 may be formed as one unit or each of them can be joined. Moreover, in either case, the material, which is directly connected to the seed crystal 13, is preferably the same material as that of the pedestal 10. In addition, in order to maintain the functions of the pedestal 10, the pedestal 10 preferably has a certain thickness capable of preventing the influences from the lid 22.

When the lid 22 and the pedestal 10 are formed separately, the lid 22 can be formed using the same material as that of the pedestal 10. The combination of the material for the lid 22 and the pedestal 10 can be selected depending on the design from the view point of ease of processing, and the like. When the lid 22 and the pedestal 10 are mechanically joined, carbon material is preferably used because of ease of processing. In addition, metals having a high melting point or the metals having a high melting point which is covered with the metal carbide is also preferably used for the same reason as that of carbon material.

Since special adhesion is not required to the joint between the pedestal 10 and the lid 22, mechanical joint or adhesive joint can be used. In addition, the pedestal 10 can also be inserted into the lid 22 to be joined. In this case, the temperature at the back surface of the pedestal 10 can be maintained lower, and the thermal deterioration of the back surface can also be prevented.

In addition, it is also possible to make the pedestal 10 with silicon carbide, and the lid 22 with graphite. In this case, the thermal conductivity of the pedestal 10 is higher than that of the lid 22. Thereby, it is possible to lower the temperature of the seed crystal relative to the temperature of the circumference members, and growth promoting effects to the seed crystal can be obtained.

As shown in FIG. 2, the silicon carbide seed crystal 13 includes a growth surface 13a for growing the silicon carbide single crystal and a connection surface 13b for being fixed with one surface 10a of the pedestal 10.

As the silicon carbide seed crystal 13, a single crystal made of silicon carbide (silicon carbide single crystal) is used.

Specifically, the silicon carbide single crystal used is a silicon carbide single crystal obtained by cutting a silicon carbide single crystal produced by the Acheson method, the Lely method, the Modified-Lely method, or the like which is disc-shaped and has a thickness of about 0.3 to about 5 mm, and grinding and polishing to obtain a desired shape. Moreover, in order to remove damages caused by the polishing, it is preferable to do the sacrificial oxidation, reactive ion-etching, chemical-mechanical polishing as the final finishing treatment for the silicon carbide seed crystal 13. In addition, after that, the surface of the seed crystal 13 made of silicon carbide is cleaned using an organic solvent, acidic solution, or alkali solution.

Below, one embodiment of the method for fixing a silicon carbide seed crystal and the method for producing a silicon carbide single crystal is explained.

### [Method for Fixing Silicon Carbide Seed Crystal]

(Surface Treatment of Pedestal and/or Seed Crystal)

In order to connect the seed crystal 13 on seed crystal side-surface 10a of the pedestal 10, the flatness and cleanliness of the pedestal 10 are important, and a surface treatment is necessary.

For example, when the pedestal 10 is formed using a silicon carbide material, the surface treatment for removing an oxide film is necessary. Specifically, after cleaning using acetone, wet-surface treatment in which the silicon carbide material is immersed into hydrochloric acid (HCl), or hydrofluoric acid (HF) can be carried out as the surface treatment. In addition, it is also possible to conduct a final surface treatment using a solution containing HCl after immersion into a mixture solution containing sulfuric acid (H₂SO₄), or phosphoric acid (H₃PO₄). Furthermore, it is also possible to remove the oxide film on the surface by dry-etching using an inert gas such as argon (Ar), or the like.

Even when the pedestal 10 is made of materials other than silicon carbide, it is possible to maintain the flatness and cleanliness of the pedestal 10 by suitably selecting chemical agents. Moreover, the dry-etching method can be used in various kinds of material.

The connection strength between the seed crystal side-surface 10a of the pedestal 10 and the seed crystal 13 which is connected on the seed crystal side-surface 10a varies depending on an oxides or moisture on the connection portion. In particular, the connection strength varies largely depending on the oxygen concentration at the connection surfaces 10a and 13b. The larger the concentration of the oxygen atoms at a connection layer is, the smaller the connection strength is. Moreover, the “connection layer” will be explained below. For example, the concentration of the oxygen atoms at the connection layer can be reduced to 1×10²⁰ atoms/cm³ or less by the surface treatment of the pedestal 10. When the concentration of the oxygen atoms at the connection layer in the seed crystal 13 exceeds 1×10²⁰ atoms/cm³, the connection strength is remarkably lowered.

Next, the surface of the seed crystal which has also been subjected to the surface treatment to remove the oxide film or the like is connected to the surface of the pedestal 10 on which the oxide film or the like is removed by the dry-surface treatment or wet-surface treatment under high vacuum conditions. Thereby, it is possible to further reduce the concentration of oxygen atoms in the connection layer. That is, it is possible to produce the connection having high strength between the pedestal 10 and the seed crystal 13.

In addition, when the connection is carried out in air, extremely high cleanliness is required. However, when the connection is carried out in a vacuum, such extremely high cleanliness is not required, and the production can be stably carried out with low cost.

When the pedestal 10 and the seed crystal 13 are connected each other such that the concentration of the oxygen atom is reduced while impurities are not remained at the connection surfaces, the pedestal 10 and the seed crystal 13 can be strongly connected each other. In this case, it is also effective to carry out dry-etching. Moreover, “impurities” are materials other than the materials for connecting the pedestal 10 and the seed crystal 13 to each other.

In addition, when the surface of the pedestal 10 and the seed crystal 13 is flat, specifically, when the root-mean-square of a roughness (rms) at the surfaces is 0.3 nm or less, in particular, a strong connection can be obtained.

For example, when the pedestal 10 and the seed crystal 13 are made of silicon carbide, such a flat surface can be obtained by the chemical mechanical polishing (CMP) using an abrasive containing colloidal silica. After the CMP, when the polished surface is further treated with an acidic solution or an alkali solution, the flatness of the surface is further improved. At the same time, foreign materials or contamination in the polishing step can also be removed. Thereby, a clean surface can be obtained.

It is preferable that the pedestal 10 and the seed crystal 13 be connected under 1×10⁻² Pa or less, preferably 1×10⁻³ Pa or less. When the polished flat surfaces are connected each other under the conditions, they can be strongly connected.

When the pedestal 10 and the seed crystal 13 are connected, it is important that each of the surfaces to be connected is irradiated with an atomic beam or ion beam to activate the surfaces. The energy of the atomic beam or ion beam is preferably 50 eV or more. Moreover, “activate” means to remove the oxide film, an impurity layer containing carbon and the like, or a contamination layer, which are on the surfaces to be connected, and cleans the surfaces thereof.

By removing the layer on the surface, it is possible to directly connect the atomic bonding of the atoms on the surfaces each other, and make a strong connection. When the irradiation is carried out to at least one of the pedestal 10 and the seed crystal 13, they can certainly be connected to each other. However, when the irradiation is carried out both of them, it is possible to further strongly connect them.

At the activated surfaces, the lattice constant in the most outer layer having a depth ranging from about 0.5 to about 20 μm is slightly different from that in other part. After the connection, such a layer having a fixed thickness is formed in the interface. This layer is called a connection layer. The irradiation of an ion beam or the like also means “formation of a connection layer”.

(Atom or Ion Irradiation step)

Examples of the irradiating species to strongly connect between the pedestal and the seed crystal include beams of hydrogen atom (H), hydrogen molecular (H₂), and hydrogen ion (H⁺). When a beam containing the elements in the area of the surface to be connected is irradiated, the connection having high strength can be obtained. When the electrical resistance at the surfaces of the pedestal and the seed crystal is high, and a beam mainly containing ions is irradiated, the surface may be charged. When electrical repulsion is caused due to this charge, it is impossible to strongly connect the pedestal and the seed crystal. Therefore, when the surface is activated by irradiating an ion beam, it is preferable that at least one of the connection surfaces of the pedestal and the seed crystal be made of a material having high electrical conductivity.

In addition, when a beam of an inert gas such as helium (He), neon (Ne), argon (Ar), krypton (Kr) or the like, which does not remarkably change the composition of the surface area of the pedestal and the seed crystal, is used, it is possible to stably activate the surface. In particular, when an atomic beam of argon (Ar) is used, the surface can be simply activated within a short amount of time. The atomic weight of helium (He) is smaller than that of argon (Ar). Due to this, when the He beam is used, a long time is required to activate the surface, which is a backward. On the other hand, when a krypton (Kr) beam, which has larger atomic weight than that of argon, is used, the surface may be damaged, which is inconvenient.

### [Connection Step]

When the surfaces of the pedestal and the seed crystal face each other and they are superposed and connected such that the mechanical stress is applied to the entire connection surfaces, the pedestal and the seed crystal can be strongly connected, which is preferable. Specifically, it is preferable to apply pressure in a range of 5 g/cm² to 200 g/cm² from the vertical direction (perpendicular direction) to the connection surfaces. Thereby, even when one or both of the pedestal and the seed crystal warp, the warpage can be corrected, and they can be connected with uniform strength.

As explained above, when the surfaces, which are activated using the atomic beam or the ion beam in a vacuum, are connected, the connection between the pedestal and the seed crystal can be carried out at low temperatures equal to 200° C. or less.

The pedestal and the seed crystal can be connected in a vacuum having aforementioned preferable vacuum degree (4×10⁻³ Pa or less) by adjusting the temperature of 200° C. or less, preferably 100° C. or less, and more preferably room temperature, and by applying pressure from the vertical direction (perpendicular direction) to the connection surfaces. When the connection is carried out at high temperatures of more than 200° C., outgas is generated from the material constituting the pedestal, and the outgas influences adverse effects on the cleanliness of the surfaces, and this may decrease the connection strength.

In the connection method according to the present embodiment, it is believed that since the atoms having atomic bonding, which is generated by the irradiation of the ion beam, are exposed, the surfaces are under activated conditions having large connection strength. Therefore, strong connection can be achieved even at room temperature. It is preferable that the connection be not carried out unnecessary high temperatures in order to avoid thermal deformation of the seed crystal or the interface between the seed crystal and the pedestal.

In addition, it is also preferable that before bringing the pedestal into contact with the seed crystal, the temperature of the pedestal and the seed crystal in the vacuum chamber be raised to a temperature, which is higher than the connection temperature, to discharge the outgas, and then the pedestal and the seed crystal be cooled to the connection temperature and connected to each other. Furthermore, it is also preferable that, before connection, the surfaces be cleaned and activated by irradiating accelerated Ar ions under high temperatures from the view point of improvement of the connection strength.

### [Method for Producing the Silicon Carbide Single Crystal]

The lid having the pedestal, on which the silicon carbide seed crystal is fixed, as explained above, is put on the body part of the crucible.

After that, the silicon carbide single crystal can be produced by a common production method.

### Example 1

In this Example, the pedestal made of polycrystal silicon carbide was used, and the silicon carbide seed crystal was fixed to the pedestal.

Specifically, as the pedestal, a polycrystal silicon carbide having a diameter of 50 mm (2-inch φ) and a thickness of 12 mm was used. As explained below, after the connection step, the surface of the pedestal, which is opposite to the surface to be fixed with the seed crystal, was processed so as to be mechanically mounted on the lid (the lid of the crucible).

As the silicon carbide seed crystal, a silicon carbide single crystal wafer of 4H (0001) C-plane having a diameter of 50 mm (2-inch φ) and a thickness of 0.8 mm was used.

### [Surface Treatment Step]

First of all, the seed crystal side-surface of the pedestal and the pedestal side-surface of the silicon carbide seed crystal were immersed into a sulfuric acid solution to remove the oxide film formed on the surface of the pedestal and the silicon carbide seed crystal.

Then, the seed crystal side-surface of the pedestal and the pedestal side-surface of the silicon carbide seed crystal were mirror-polished by CMP using the abrasion containing colloidal silica. The root-mean-square of a roughness (rms) at the surfaces of the seed crystal side-surface of the pedestal and the pedestal side-surface of the silicon carbide seed crystal after polishing was respectively 0.20 nm and 0.15 nm.

### [Atoms or Ions Irradiation Step]

Next, in a vacuum device which is connection device, the lid including the polished pedestal and the silicon carbide seed crystal were introduced, and the air inside of the vacuum device was discharged to 2×10⁻⁵ Pa or less. After that, while heating the lid including the pedestal to about 800° C. in a vacuum, Ar⁺ ions accelerated by 800 eV energy were irradiated to the surface of the pedestal. Thereby, the connection layer was produced at the surface of the pedestal.

Similarly, Ar⁺ ions accelerated by 800 eV energy were also irradiated to the surface of the silicon carbide seed crystal at about 800° C. Thereby, the connection layer was also produced at the surface of the silicon carbide seed crystal.

After that, the temperature of the lid including the pedestal and the silicon carbide seed crystal was lowered to room temperature.

Then, the surfaces of both the pedestal and the silicon carbide seed crystal were irradiated with neutral Ar⁺ beam which is neutered by collision with electrons for 3 minutes.

### [Connection Step]

Then, in the vacuum device being maintained in a vacuum, both the surfaces of pedestal and the silicon carbide seed crystal were superposed, and load was applied such that the pressure at the surfaces reaches 20 g/cm², and they were connected at room temperature.

### [Production of Lid for Crucible]

The pedestal fixed with the silicon carbide seed crystal in this way was mechanically attached to the member made of graphite, which becomes the lid of the crucible, to produce the lid for the crucible.

[Production of Silicon Carbide Single crystal]

The produced lid for the crucible, which is made of graphite, was arranged on the body part of the crucible, and then the silicon carbide single crystal was produced.

The crystal growth was carried out by making temperature gradient in the crucible such that the temperature of the silicon carbide seed crystal is lower than that of the silicon carbide raw material powder, while heating silicon carbide raw material powder to 2,450° C., and maintaining the pressure inside the crucible to 3 Torr. The crystal was grown under common conditions in this way.

The produced crystal had a thickness of 20 mm, penetration defects generated from the interface between the pedestal and the seed crystal were not observed. A silicon carbide single crystal having high quality was produced.

### Example 2

In this Example, as the material for the pedestal, dense graphite was used, and the silicon carbide seed crystal was fixed to the pedestal.

Specifically, a lid having a diameter of 50 mm combined with the pedestal, which is a protrusion having a diameter of 20 mm and a height of 10 mm formed at the center of the lid, was used.

As the silicon carbide seed crystal, a silicon carbide single crystal wafer of 4H (0001) C-plane having a diameter of 20 mm and a thickness of 0.8 mm was used.

### [Surface Treatment Step]

First of all, the seed crystal side-surface of the pedestal was mirror-polished so as to be flat. After that, impurities on the surface of and inside of the pedestal were removed by baking in a vacuum and inert gas.

### [Atoms or Ions Irradiation Step]

Similarly in Example 1, in a vacuum device which is connection device, the lid combined with the pedestal and the silicon carbide single crystal were introduced. Also similarly in Example 1, the Ar⁺ ions irradiation at 800° C. was also carried out before connection. Then, the surfaces of both the pedestal and the silicon carbide seed crystal were irradiated with neutral Ar⁺ beam which is neutered by collision with electrons for 3 minutes.

### [Connection Step]

Then, in the vacuum device being maintained in a vacuum, both of the surfaces of pedestal and the silicon carbide seed crystal were superposed, and load was applied such that the pressure at the surfaces reaches 20 g/cm², and they were connected at room temperature.

### [Production for Silicon Carbide Single Crystal]

The produced lid combined with the pedestal fixed with the silicon carbide seed crystal was arranged on the body part of the crucible, which is made of graphite, and then the silicon carbide single crystal was produced.

The penetration defects generated from the interface between the pedestal and the seed crystal were not observed in the produced crystal. The silicon carbide single crystal having high quality was produced.

### INDUSTRIAL APPLICABILITY

According to the method for fixing a silicon carbide seed crystal, and the method for producing a silicon carbide single crystal of present invention, it is possible to product a silicon carbide single crystal having high quality and no penetration defects.

### EXPLANATION OF REFERENCE SYMBOL

1 vacuum chamber

3 heating device

5 silicon carbide raw material powder

6 crucible made of graphite
10 pedestal
10a seed crystal side-surface
13 silicon carbide seed crystal

13b connection surface
21 body part
22 lid
100 single crystal growth device

1. A method for fixing a silicon carbide seed crystal on a pedestal including:
a step of mirror polishing a surface of a pedestal on which a silicon carbide seed crystal is to be fixed;
a step of irradiating atoms or ions to at least one of a seed crystal-side surface of the pedestal on which the silicon carbide seed crystal is to be fixed and a pedestal side-surface of the silicon carbide seed crystal which is to be fixed on the pedestal, in a vacuum; and
a step of directly connecting the seed crystal side-surface of the pedestal and the pedestal side-surface of the silicon carbide seed crystal by bringing them into close contact and applying pressure to them in a vacuum.

2. The method for fixing a silicon carbide seed crystal according to claim 1, wherein the method further includes a step of polishing the pedestal side-surface of the silicon carbide seed crystal before the step of irradiating.

3. The method for fixing a silicon carbide seed crystal according to claim 1, wherein the seed crystal side-surface of the pedestal and/or the pedestal side-surface of the silicon carbide seed crystal is mirror polished such that a root-mean-square of a roughness at the surface is 0.3 nm or less in the step of mirror polishing.

4. The method for fixing a silicon carbide seed crystal according to claim 1, wherein the atoms and ions irradiated in the step of irradiating is one selected from the group consisting of hydrogen atoms (H), hydrogen molecules (H₂), and hydrogen ions (H⁺).

5. The method for fixing a silicon carbide seed crystal according to claim 1, wherein the atoms and ions irradiated in the step of irradiating is at least one selected from the group consisting of helium (He), neon (Ne), argon (Ar), and krypton (Kr).

6. The method for fixing a silicon carbide seed crystal according to claim 1, wherein the method further includes a step of wet-etching or dry-etching at least one of the seed crystal side-surface of the pedestal and the pedestal side-surface of the silicon carbide seed crystal before the step of irradiating.

7. The method for fixing a silicon carbide seed crystal according to claim 1, wherein a temperature for directly connecting the seed crystal side-surface of the pedestal and the pedestal side-surface of the silicon carbide seed crystal is room temperature or higher and 200° C. or lower.

8. A method for producing a silicon carbide single crystal wherein using the method according to claim 1, a silicon carbide single crystal is grown on the silicon carbide seed crystal by supplying a sublimation gas containing a silicon carbide raw material to the silicon carbide seed crystal which is fixed on the pedestal made of a carbon material.
